(19) United States
(12) Patent Application Publication
(10) Pub. No.: US 2008/0169490 A1
(43) Pub. Date: Jul. 17, 2008

(54) SEMICONDUCTOR DEVICE AND MANUFACTURING METHOD THEREOF

(75) Inventor: Shinichi KAWAI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/053,926

(22) Filed: Mar. 24, 2008

Related U.S. Application Data
(63) Continuation of application No. PCT/JP2005/017513, filed on Sep. 22, 2005.

(51) Int. Cl. H01L 29/76

(52) U.S. Cl. 257/288

(57) ABSTRACT

Disclosed is a semiconductor device using an SOI substrate and improving carrier mobility of transistors. Over a thin Si layer formed over a Si substrate through a buried insulating film, a gate electrode is formed through a gate insulating film. On both sides of the gate electrode, S/D layers are formed which penetrate through the Si layer and the buried insulating film into the Si substrate and which have a crystal structure with a lattice constant different from that of the Si substrate or the Si layer. Since a channel region is formed within the Si layer, the short channel effect can be suppressed. In addition, since the S/D layer having a crystal structure different from that of a Si crystal is thickly formed to reach the Si substrate, sufficient stress is generated in the channel region, so that the carrier mobility can be efficiently improved.

### CROSS-REFERENCE TO RELATED APPLICATIONS

This application is a continuing application, filed under 35 U.S.C. §111(a), of International Application PCT/JP2005/017513, filed Sep. 22, 2005.

### BACKGROUND OF THE INVENTION

1. Field of the Invention

The present invention relates to a semiconductor device and a method of manufacturing the semiconductor device. More particularly, the present invention relates to a semiconductor device having a MIS (Metal Insulator Semiconductor) field effect transistor. The invention also pertains to a method of manufacturing the semiconductor device.

2. Description of the Related Art

To achieve the speeding up of a MOS (Metal Oxide Semiconductor) field effect transistor (referred to as a “MOS transistor”), increase in a driving current amount is effective. Recently, the following transistor structure is being taken notice of. That is, a source/drain (S/D) layer is made of materials having a lattice constant different from that of a substrate, thereby causing lattice distortion to cause a stress in a channel region formed within the substrate.

FIG. 33 is a schematic plan view showing an essential part of one example of a conventional MOS transistor and FIG. 34 is a schematic sectional view taken along the line X-X of FIG. 33.

A MOS transistor 100 shown in FIGS. 33 and 34 has the following structure. That is, within an element region delimited by an STI (Shallow Trench Isolation) 102 of a silicon (Si) substrate 101, a gate electrode 104 is formed through a gate insulating film 103, and a sidewall spacer 105 is formed on a side wall of the gate electrode 104. Within the Si substrate 101 on both sides of the gate electrode 104, S/D extension regions 107 having a predetermined impurity concentration and sandwiching a channel region 106 are formed, and S/D layers 108 having a higher impurity concentration are formed within the Si substrate 101 outside the S/D extension regions 107.

When this MOS transistor 100 is an n-channel MOS transistor (referred to as an “n-MOS transistor”), the S/D layer 108 is made of, for example, silicon carbide (SiC) which is a compound of silicon (Si) and carbon (C) having an atomic radius smaller than that of silicon. Thereby, such lattice distortion that causes a tensile stress in Si crystals of the channel region 106 occurs in this MOS transistor 100.

On the other hand, when this MOS transistor 100 is a p-channel MOS transistor (referred to as a “p-MOS transistor”), the S/D layer 108 is made of, for example, silicon germanium (SiGe) which is a compound of silicon (Si) and germanium (Ge) having an atomic radius larger than that of silicon. Thereby, such lattice distortion that causes a compressive stress in Si crystals of the channel region 106 occurs in this MOS transistor 100.

By adopting the above-described structure, increase in carrier mobility of each of the n-MOS transistor and the p-MOS transistor has been achieved. An effect of the stress generated in the channel region 106 on the carrier mobility is considered to more increase as the S/D layer 108 made of SiC or SiGe is made thicker (See, e.g., U.S. Pat. No. 6,621,131).

As a technique for achieving speeding up and high integration of transistors, miniaturization based on a scaling law becomes a mainstream. In order to suppress a short channel effect which may occur in the miniaturization, adoption of SOI (Silicon On Insulator) substrates is considered to be effective.

FIG. 35 is a schematic sectional view showing an essential part of another example of a conventional MOS transistor.

In a MOS transistor 200 shown in FIG. 35, an SOI substrate is used, in which a buried insulating film 202 is formed over a Si substrate 201 as a support substrate, and a thin Si layer 203 is formed over the film 202. Within an element region delimited by an STI 204 of the Si layer 203, a gate electrode 206 is formed through a gate insulating film 205, and a sidewall spacer 207 is formed on a side wall of the electrode 206. Within the Si layer 203, S/D extension regions 209 having a predetermined impurity concentration and sandwiching a channel region 208 immediately below the gate electrode 206 are formed. Outside the region 209, an S/D region 210 obtained by ion-implanting impurities of higher concentration into the Si layer 203 is formed between the region 209 and the STI 204.

In this MOS transistor 200, since the buried insulating film 202 is formed between the Si substrate 201 and the Si layer 203 in which a transistor structure is formed, the thin channel region 208 can be formed. Therefore, even if a channel length is short, control over the channel region 208 by the gate electrode 206 can be performed with high accuracy.

When a transistor structure shown in FIGS. 33 and 34 and that shown in FIG. 35 can be combined with each other, a high-performance MOS transistor capable of improving carrier mobility as well as suppressing a short channel effect is realized.

FIG. 36 shows a structure example of a MOS transistor.

A MOS transistor 300 shown in FIG. 36 has the following structure. That is, in a conventional MOS transistor using an SOI substrate, an S/D region formed by ion implantation into a thin Si layer is simply replaced by an S/D layer having a crystal structure with a lattice constant different from that of an Si crystal.

More specifically, the transistor 300 has the following structure. Within an element region delimited by an STI 304 of a thin Si layer 303 formed through a buried insulating film 302 over an Si substrate 301, a gate electrode 306 is formed through a gate insulating film 305, and a sidewall spacer 307 is formed on a side wall of the electrode 306. Within the Si layer 303, S/D extension regions 309 sandwiching a channel region 308 immediately below the gate electrode 306 are formed. Outside the region 309, an S/D layer 310 made of SiC or SiGe that causes a stress in the channel region 308 is formed between the region 309 and the STI 304.

As described above, for suppressing the short channel effect, it is effective to use the SOI substrate to reduce the thickness of the channel region. Meanwhile, for improving the carrier mobility, it is effective to form the S/D layer using SiC or SiGe to cause a stress in the channel region and further, it is effective to thickly form the S/D layer.

In reality, in the transistor 300 shown in FIG. 36, a thickness of the Si layer 303 in which the channel region 308 is formed and that of the S/D layer 310 are structurally the same. Accordingly, there exists a trade-off relationship between suppressing the short channel effect by reducing the thickness of the channel region 308 and improving the carrier mobility by forming the thick S/D layer 310 to cause a stress in the channel region 308.

In order to cause a stress in the channel region 308 within the Si layer 303 by the S/D layer 310 to obtain a certain level of carrier mobility improving effect, it is desired that the S/D layer 310 itself has a preferable crystal condition with no polycrystal portion.

When forming the S/D layer 310, for example, the following method is considered. That is, after the formation of the gate electrode 306, the S/D extension region 309 and the sidewall spacer 307, the Si layer 303 in a region for the S/D layer 310 to be formed is removed and SiC or SiGe is epitaxially grown in the resulting region. However, it is considered that the method of epitaxially growing SiC or SiGe from the thin Si layer 303 over the buried insulating film 302 and finally obtaining the S/D layer 310 with a good crystal condition is technically very difficult.

### SUMMARY OF THE INVENTION

According to one aspect of an embodiment, there is provided a semiconductor device using a substrate including a semiconductor substrate having formed thereover a thin film semiconductor layer through a buried insulating film. This device has: a gate electrode formed over the thin film semiconductor layer through a gate insulating film; and a source/drain layer formed on both sides of the gate electrode, which penetrates through the thin film semiconductor layer and the buried insulating film into the semiconductor substrate and which has a crystal structure with a lattice constant different from that of the thin film semiconductor layer.

According to another aspect of an embodiment, there is provided a method of manufacturing a semiconductor device using a substrate including a semiconductor substrate having formed thereover a thin film semiconductor layer through a buried insulating film. This method has the steps of: (a) forming a gate electrode over the thin film semiconductor layer through a gate insulating film; (b) forming a concave portion on both sides of the gate electrode, the concave portion penetrating through the thin film semiconductor layer and the buried insulating film into the semiconductor substrate; and (c) forming in the concave portion a source/drain layer having a crystal structure with a lattice constant different from that of the thin film semiconductor layer.

### BRIEF DESCRIPTION OF THE DRAWINGS

FIG. 1 shows a principle configuration of a semiconductor device.

FIG. 2 is a schematic sectional view showing an essential part of a semiconductor device according to a first embodiment.

FIG. 3 is a schematic plan view showing an essential part of a first forming step of the semiconductor device according to the first embodiment.

FIG. 4 is a schematic sectional view taken along the line A-A in FIG. 3.

FIG. 5 is a schematic plan view showing an essential part of a second forming step of the semiconductor device according to the first embodiment.

FIG. 6 is a schematic sectional view taken along the line B-B in FIG. 5.

FIG. 7 is a schematic plan view showing an essential part of a third forming step of the semiconductor device according to the first embodiment.

FIG. 8 is a schematic sectional view taken along the line C-C in FIG. 7.

FIG. 9 is a schematic plan view showing an essential part of a fourth forming step of the semiconductor device according to the first embodiment.

FIG. 10 is a schematic sectional view taken along the line D-D in FIG. 9.

FIG. 11 is a schematic plan view showing an essential part of a fifth forming step of the semiconductor device according to the first embodiment.

FIG. 12 is a schematic sectional view taken along the line E-E in FIG. 11.

FIG. 13 is a schematic plan view showing an essential part of a sixth forming step of the semiconductor device according to the first embodiment.

FIG. 14 is a schematic sectional view showing an essential part of a semiconductor device according to a second embodiment.

FIG. 15 is a schematic plan view showing an essential part of a fourth forming step of the semiconductor device according to the second embodiment.

FIG. 16 is a schematic sectional view taken along the line G-G in FIG. 15.

FIG. 17 is a schematic plan view showing an essential part of a fifth forming step of the semiconductor device according to the second embodiment.

FIG. 18 is a schematic sectional view taken along the line H-H in FIG. 17.

FIG. 19 is a schematic plan view showing an essential part of a sixth forming step of the semiconductor device according to the second embodiment.

FIG. 20 is a schematic sectional view showing an essential part of a semiconductor device according to a third embodiment.

FIG. 21 is a schematic sectional view showing an essential part of a punch-through stopper layer forming step according to the third embodiment.

FIG. 22 is a schematic sectional view showing an essential part of a semiconductor device according to a fourth embodiment.

FIG. 23 is a schematic sectional view showing an essential part of a punch-through stopper layer forming step according to the fourth embodiment.

FIG. 24 is a schematic sectional view showing an essential part of a semiconductor device according to a fifth embodiment.

FIG. 25 is a schematic sectional view showing an essential part of a punch-through stopper layer forming step according to the fifth embodiment.

FIG. 26 is a schematic sectional view showing an essential part of a first forming step of a semiconductor device according to a sixth embodiment.

FIG. 27 is a schematic sectional view showing an essential part of a second forming step of the semiconductor device according to the sixth embodiment.

FIG. 28 is a schematic sectional view showing an essential part of a third forming step of the semiconductor device according to the sixth embodiment.

FIG. 29 is a schematic sectional view showing an essential part of a fourth forming step of the semiconductor device according to the sixth embodiment.

FIG. 30 is a schematic sectional view showing an essential part of a fifth forming step of the semiconductor device according to the sixth embodiment.

FIG. 31 is a schematic sectional view showing an essential part of a sixth forming step of the semiconductor device according to the sixth embodiment.

FIG. 32 is a schematic sectional view showing an essential part of a seventh forming step of the semiconductor device according to the sixth embodiment.

FIG. 33 is a schematic plan view showing an essential part of one example of a conventional MOS transistor.

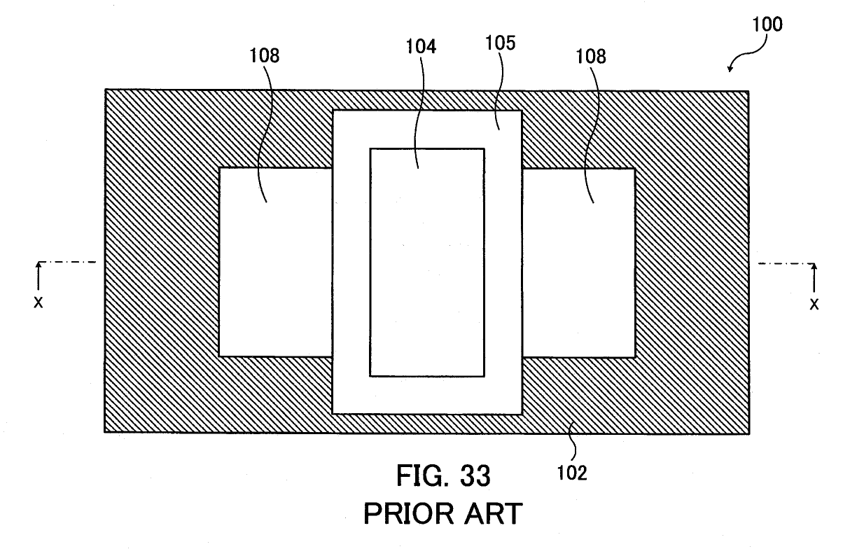

FIG. 34 is a schematic sectional view taken along the line X-X in FIG. 33.

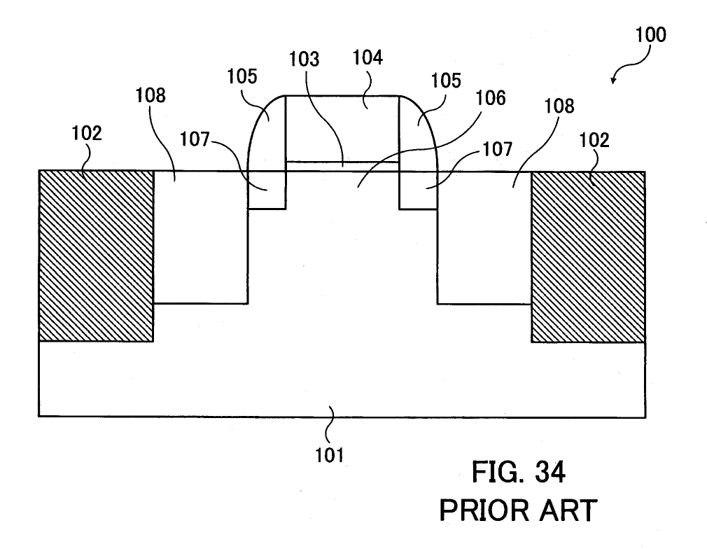

FIG. 35 is a schematic sectional view showing an essential part of another example of a conventional MOS transistor.

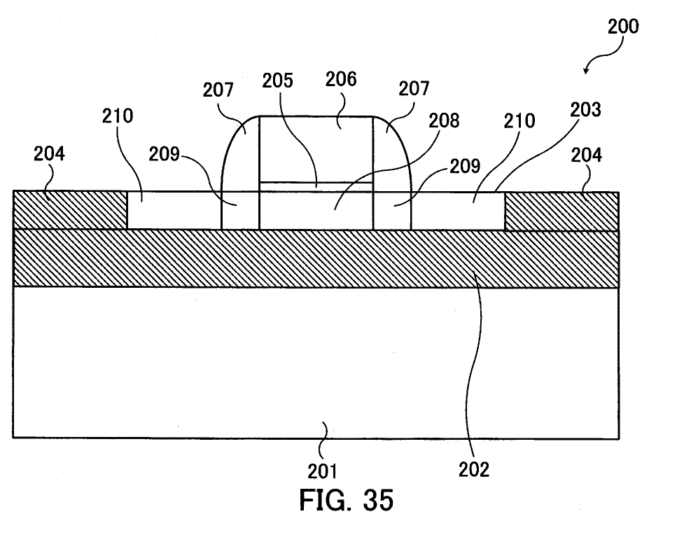

FIG. 36 shows a structure example of a MOS transistor.

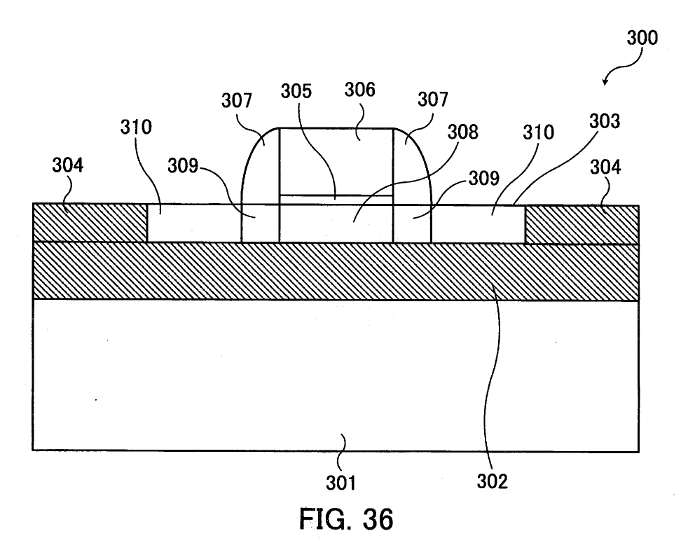

### DESCRIPTION OF THE PREFERRED EMBODIMENTS

Preferred embodiments of the present invention will be described in detail below with reference to the accompanying drawings, wherein like reference numerals refer to like elements throughout.

First, a principle configuration will be described.

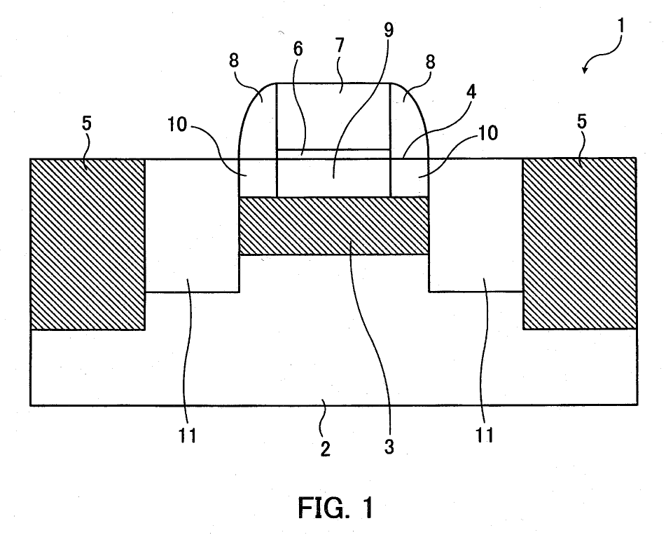

FIG. 1 shows a principle configuration of a semiconductor device.

In a semiconductor device 1 shown in FIG. 1, an SOI substrate including an Si substrate 2, a buried insulating film 3 made of silicon dioxide (SiO₂) and a thin Si layer 4 is used. Over the Si layer 4 within an element region delimited by an STI 5 reaching the Si substrate 2 of the SOI substrate, a gate electrode 7 made of polysilicon is formed through a gate insulating film 6 such as a silicon oxi-nitride (SiON) film. Further, a sidewall spacer 8 made of silicon nitride (SiN) is formed on a side wall of the gate electrode 7. Within the Si layer 4 immediately below the sidewall spacer 8, S/D extension regions 10 sandwiching a channel region 9 formed within the Si layer 4 are formed. Further, S/D layers 11 made of SiC or SiGe, which causes a stress in the channel region 9, are formed outside the S/D extension regions 10. The S/D layers 11 are formed with an impurity concentration higher than that of the S/D extension regions 10. Further, the S/D layers are formed by epitaxial growth from surfaces of the Si substrate 2 and the Si layer 4 so as to sandwich the Si layer 4 from a lateral direction as well as to sandwich the buried insulating film 3 and a part of the Si substrate 2 from a lateral direction.

In the semiconductor device 1 having the above-described transistor structure, a region immediately below the gate electrode 7 between the S/D layers 11 has an SOI structure in which the Si substrate 2 as a support substrate, the buried insulating film 3 and the Si layer 4 as a thin film semiconductor layer are disposed sequentially from a lower layer side. Therefore, a thickness of the channel region 9 formed within the Si layer 4 immediately below the gate electrode 7 is restricted by the buried insulating film 3 and as a result, control over the channel region 9 by the gate electrode 7 can be performed with high accuracy.

In this semiconductor device 1, the S/D layer 11 is formed by epitaxial growth from surfaces of the Si substrate 2 and the Si layer 4. Further, in this semiconductor device 1, the S/D layer 11 penetrates through the Si layer 4 and buried insulating film 3 of the SOI substrate and the S/D layer 11 having a thickness enough to cause a predetermined stress in the channel region 9 is formed. Therefore, improvement in the carrier mobility due to the S/D layer 11 obtained by epitaxial growth can be effectively achieved.

Accordingly, according to the semiconductor device 1 having such a structure, both of suppression in the short channel effect and improvement in the carrier mobility can be satisfied and therefore, the high-speed and high-performance semiconductor device 1 can be realized.

Note, however, that in such a semiconductor device 1, if the S/D layer 11 deeply penetrates into the Si substrate 2 side, when the channel length is reduced, punch-through may occur within the Si substrate 2 between the S/D layers 11 sandwiching the channel region 9. Accordingly, with this point in view, a thickness of the S/D layer 11 must be set. In addition, in order to avoid the problem of punch-through, a predetermined conductivity type impurity layer to be used as a potential barrier may be formed between the S/D layers 11 to cope with the problem. This point will be described later.

Here, description is made on a case where the SOI substrate including the Si substrate 2, the buried insulating film 3 and the Si layer 4 is used; however, as long as a substrate to be used is a substrate having a structure including a support substrate having formed thereover a thin film semiconductor layer through a buried insulating film, materials of the respective layers within the substrate are not limited to the above-described example. Note, however, that when using such a substrate, an S/D layer is formed using materials capable of epitaxial growth from a support substrate and a thin film semiconductor layer as well as capable of obtaining a crystal structure with a lattice constant different from that of the thin film semiconductor layer in which a channel region is formed.

Hereinafter, description will be made in detail by giving specific examples. Note, however, that in the following description, the same or corresponding elements in FIG. 1 will be indicated by the same reference numerals as those in FIG. 1 and the detailed description will be omitted.

First, a first embodiment will be described.

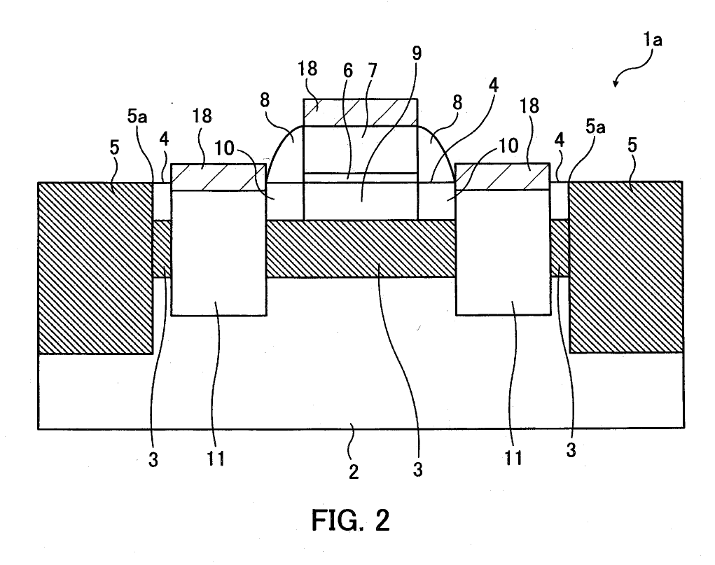

FIG. 2 is a schematic sectional view showing an essential part of a semiconductor device according to the first embodiment.

In a semiconductor device 1a according to the first embodiment, an SOI substrate including an Si substrate 2, a buried insulating film 3 and an Si layer 4 is used. Over the Si layer 4 in an element region delimited by an STI reaching the Si substrate 2 of the SOI substrate, a gate electrode 7 is formed through a gate insulating film 6 formed by thermal oxidation. Further, a sidewall spacer 8 is formed on a side wall of the gate electrode 7. Within the Si layer 4 immediately below the sidewall spacer 8, a p-type or n-type S/D extension region 10 with a predetermined impurity concentration is formed. Further, a p-type or n-type S/D layer 11 with an impurity concentration higher than that of the region 10 is formed outside the region 10.

In this semiconductor device 1a, the S/D layer 11 is formed inside by a predetermined distance from a boundary 5a with the STI 5. Further, nickel (Ni) silicide 18 is formed over a surface of the gate electrode 7 and a surface of the S/D layer 11.

A forming method of the semiconductor device 1a according to the first embodiment having the above-described structure will be described with reference to FIG. 2 and FIGS. 3 to 13.

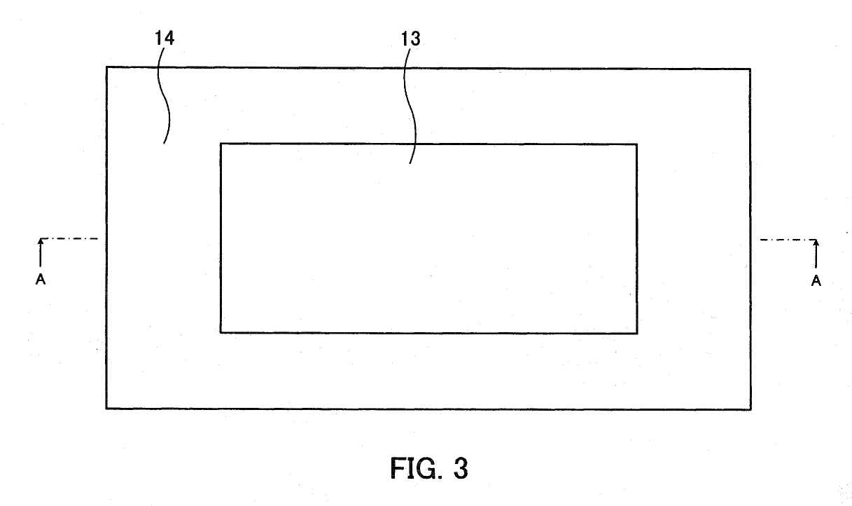

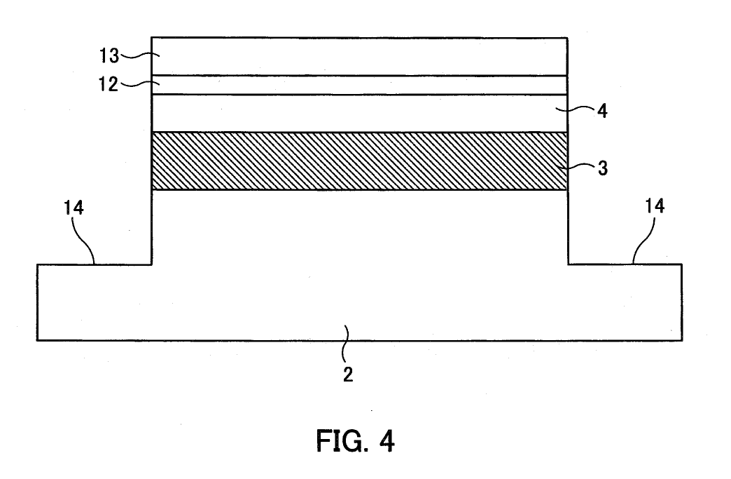

FIG. 3 is a schematic plan view showing an essential part of a first forming step of the semiconductor device according to the first embodiment. FIG. 4 is a schematic sectional view taken along the line A-A in FIG. 3.

First, an SOI substrate including a support substrate having formed thereover a thin film semiconductor layer through an insulating layer is prepared. For such an SOI substrate, for example, a substrate including the Si substrate 2 having formed thereover the Si layer 4 with a thickness of about 50 nm through the SiO₂ buried insulating film 3 with a thickness of about 100 nm can be used.

In addition, for the SOI substrate, any of the following substrates can be used: an SIMOX (Separation by IMplanted OXygen) substrate in which an insulating layer with a constant depth is formed over a support substrate by oxygen implantation, a bonding SOI substrate in which an insulating layer is sandwiched between a support substrate and a thin film semiconductor layer, and a substrate formed using other methods.

After preparing the SOI substrate, element isolation is performed as follows. By a CVD (Chemical Vapor Deposition) method, a thermally-oxidized film having a thickness of about 10 nm as a first mask layer 12 is deposited over the entire surface of the Si layer 4 and a SiN film having a thickness of about 100 nm as a second mask layer 13 is deposited over the entire surface of the first mask layer 12. Subsequently, a resist mask is formed in a region corresponding to an element region over the second mask layer 13 and anisotropic dry etching is performed, thereby removing an element isolation insulating film, namely, the second and first mask layers 13 and 12 of a STI 5 forming portion. After removal of the resist mask, anisotropic dry etching is performed using as masks the first and second mask layers 12 and 13 remaining in a region corresponding to the element region. Thereby, the Si layer 4 and the buried insulating film 3 are removed and further, the Si substrate 2 is removed up to a depth of about 10 to 20 nm from a boundary with the buried insulating film 3. Thus, a trench 14 is formed.

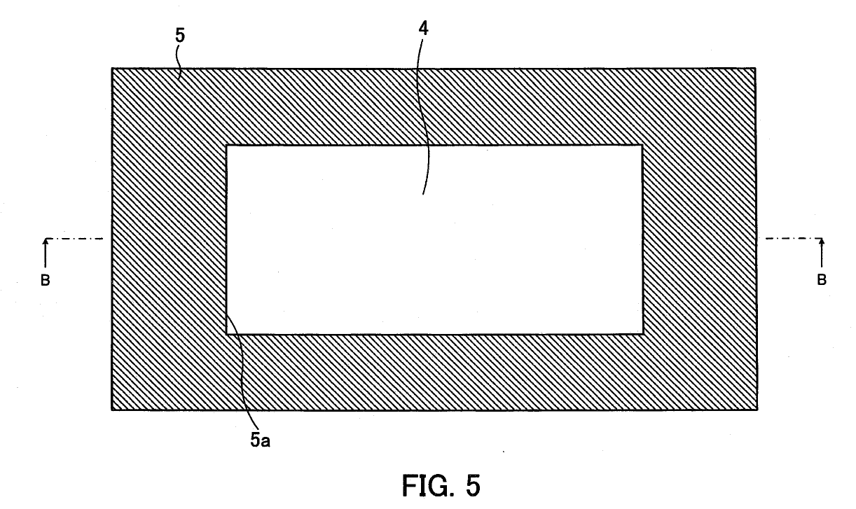

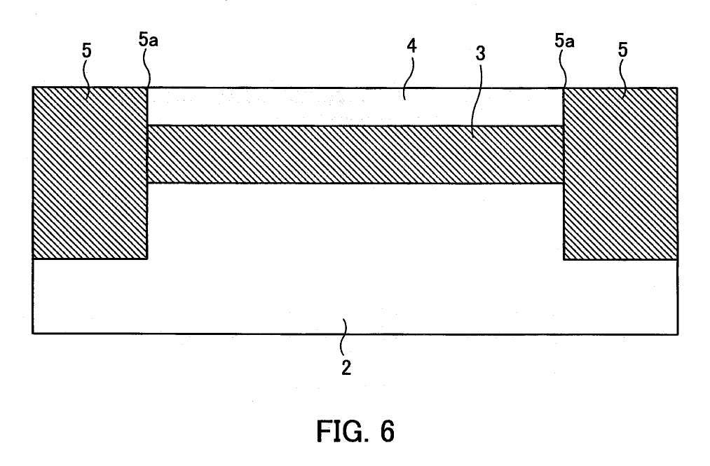

FIG. 5 is a schematic plan view showing an essential part of a second forming step of the semiconductor device according to the first embodiment. FIG. 6 is a schematic sectional view taken along the line B-B in FIG. 5.

After the formation of the trench 14, a high-density plasma oxide film having a thickness of about 250 to 400 nm is deposited over the entire surface and planarized by CMP (Chemical Mechanical Polishing) using the second mask layer 13 as a stopper. Thereby, the STI 5 is formed in the trench 14 shown in FIGS. 3 and 4. Thereafter, the second and first mask layers 13 and 12 are removed.

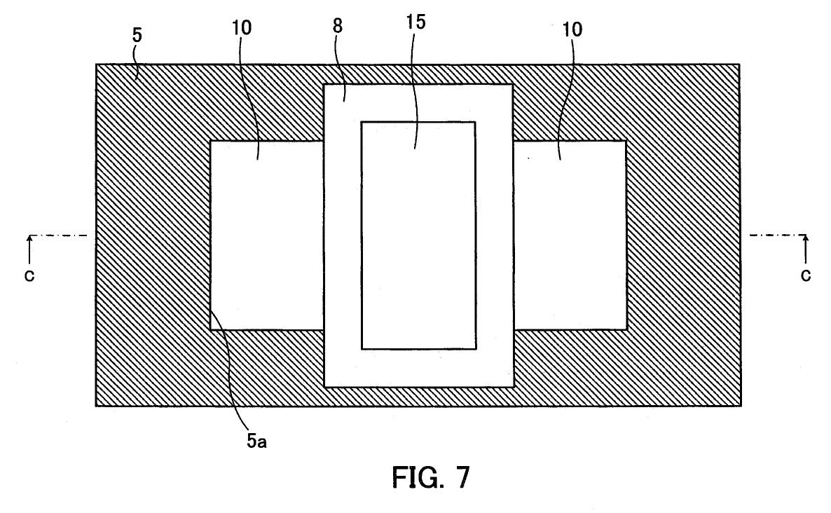

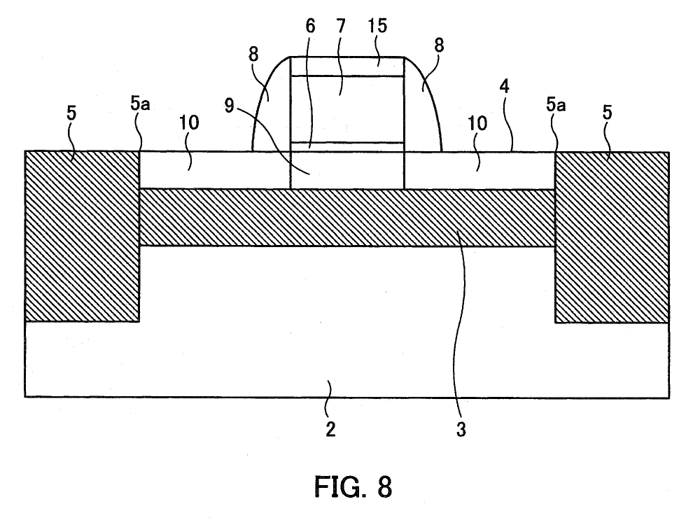

FIG. 7 is a schematic plan view showing an essential part of a third forming step of the semiconductor device according to the first embodiment, and FIG. 8 is a schematic sectional view taken along the line C-C in FIG. 7.

After the formation of the STI 5, impurities for threshold voltage adjustment are ion-implanted into the Si layer 4. When a transistor to be formed is an n-MOS transistor, for example, boron (B) is used as a p-type impurity and ion implantation is performed under conditions of acceleration energy of about 15 keV and a dose of about 2×10¹³ to 3×10¹³ cm⁻². When a transistor to be formed is a p-MOS transistor, for example, phosphorus (P) is used as an n-type impurity and ion implantation is performed under conditions of acceleration energy of about 40 keV and a dose of about 2×10¹³ to 3×10¹³ cm⁻². After the ion implantation, a thermally-oxidized film having a thickness of about 1.5 nm is thermally nitrided at a temperature condition of about 950 to 1050° C. in a nitrogen (N₂) atmosphere to form a SiON film having a thickness of about 2 nm. Thereby, a gate insulating film 6 is formed over the entire surface of the Si layer 4.

Then, polysilicon is deposited as a gate electrode layer over the gate insulating film 6 to a thickness of about 100 nm and a SiN film is deposited as a cap layer over the gate electrode layer to a thickness of about 10 nm. Thereafter, when a transistor to be formed is an n-MOS transistor, for example, P is ion-implanted under conditions of a dose of about 8×10¹⁵ cm⁻². When a transistor to be formed is a p-MOS transistor, for example, B is ion-implanted under conditions of a dose of about 8×10¹⁵ cm⁻². After the ion implantation, patterning is performed to form a desired shape by anisotropic etching, thereby forming the gate electrode 7 and the gate cap layer 15.

After the formation of the gate electrode 7 and the gate cap layer 15, ion implantation for forming the S/D extension region 10 is performed into the Si layer 4 using the gate electrode 7 and the gate cap layer 15 as masks. When a transistor to be formed is an n-MOS transistor, for example, arsenic (As) is ion-implanted under conditions of a dose of about 6×10¹⁴ cm⁻². When a transistor to be formed is a p-MOS transistor, for example, B is ion-implanted under conditions of a dose of about 6×10¹⁴ cm⁻². Thereby, the S/D extension regions 10 are formed within the Si layer 4 on both sides of the gate electrode 7 and the gate cap layer 15. In a region located immediately below the gate electrode 7 and sandwiched between the S/D extension regions 10, the channel region 9 is formed.

Thereafter, a SiN film having a thickness of about 30 nm is deposited over the entire surface and anisotropic etching is performed, thereby forming the sidewall spacer 8 on side walls of the gate electrode 7 and the gate cap layer 15.

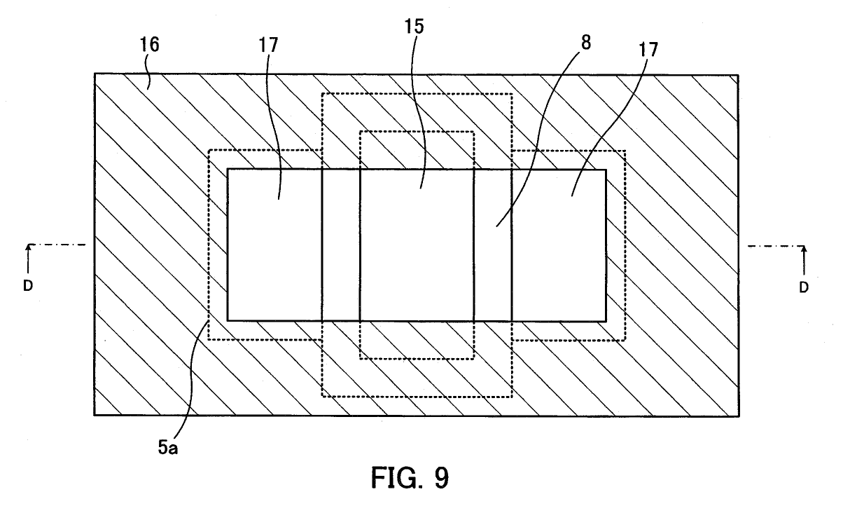

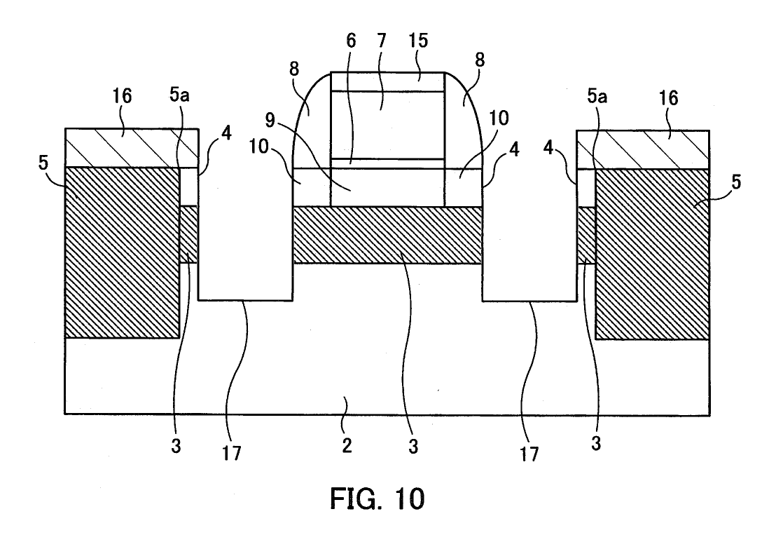

FIG. 9 is a schematic plan view showing an essential part of a fourth forming step of the semiconductor device according to the first embodiment, and FIG. 10 is a schematic sectional view taken along the line D-D in FIG. 9.

After the formation of the sidewall spacer 8, a SiN film having a thickness of about 10 nm is deposited over the entire surface. Then, using a resist mask, the SiN film is etched such that an element region on an inner side of the STI 5, for example, on an inner side by about 5 to 10 nm from the boundary 5a with the STI 5 is opened. Thereby, a third mask layer 16 is formed.

After removal of the resist, the Si layer 4, the buried insulating film 3 and the Si substrate 2 by a thickness of about 10 to 20 nm are etched using as masks the third mask layer 16, the gate cap layer 15 and the sidewall spacer 8. At that time, first, the Si layer 4 of the opening portion is anisotropically dry etched using a mixed gas of hydrogen bromide (HBr) and oxygen (O₂) as an etchant. Next, the exposed buried insulating film 3 is anisotropically dry etched using carbon tetrafluoride (CF₄) as an etchant. Finally, the exposed Si substrate 2 is anisotropically dry etched using a mixed gas of hydrogen bromide (HBr) and oxygen (O₂) as an etchant. Thereby, a concave portion 17 reaching the Si substrate 2 is formed in the opening portion of the third mask layer 16.

The reason why the third mask layer 16 is formed up to the inner side by a constant distance from the boundary 5a with the STI 5 in this step is to prevent the STI 5 near the boundary 5a from being etched together with the buried insulating film 3 during etching of the buried insulating film 3.

When etching the Si layer 4, the buried insulating film 3 and the Si substrate 2 using the third mask layer 16 and the like as masks, the Si substrate 2 is etched by a thickness of about 10 to 20 nm; however, a thickness to be etched is not limited thereto. In the concave portion 17 formed by this etching, the S/D layer 11 is formed by epitaxial growth as described later. Therefore, in the etching at this stage, it is only necessary to create a state where the buried insulating film 3 in a predetermined region is removed and the Si substrate 2 therebelow is exposed. Accordingly, when a depth of the S/D layer 11 capable of generating a required stress can be secured as described above, the Si substrate 2 is not required to be etched more deeply than necessary.

Further, in order to secure a withstand pressure between the S/D layers 11 of adjacent elements isolated by the STI 5, it is desired that a bottom of the S/D layer 11 is located at a position shallower than that of the STI 5. Accordingly, in this step, the concave portion 17 is formed more shallowly than the STI 5.

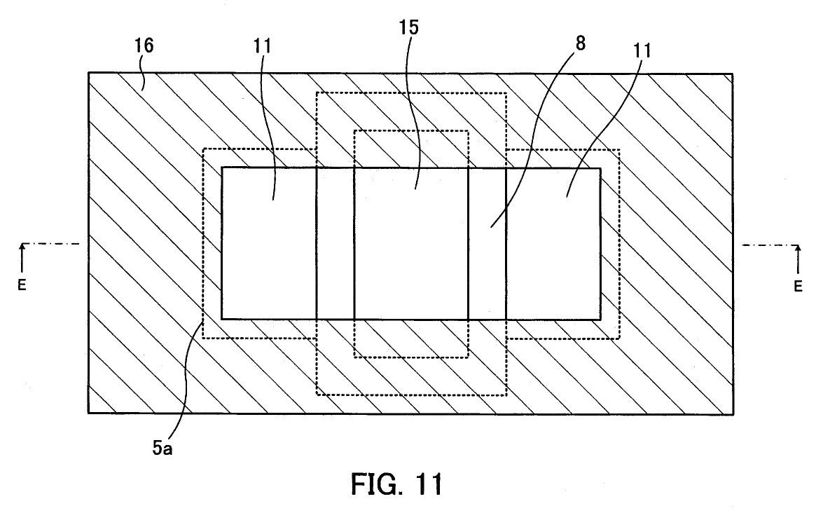

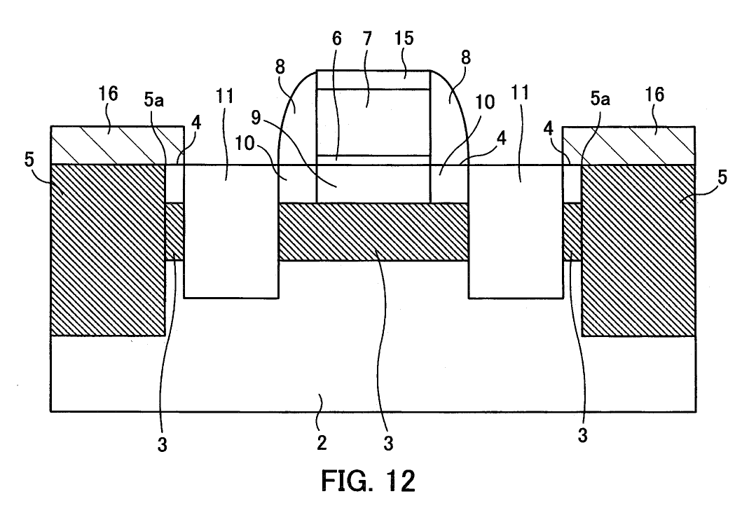

FIG. 11 is a schematic plan view showing an essential part of a fifth forming step of the semiconductor device according to the first embodiment, and FIG. 12 is a schematic sectional view taken along the line E-E in FIG. 11.

After the formation of the concave portion 17, epitaxial growth is performed. When a transistor to be formed is an n-MOS transistor, n-doped SiC is epitaxially grown in the concave portion 17. When a transistor to be formed is a p-MOS transistor, p-doped SiGe is epitaxially grown in the concave portion 17.

When epitaxially growing n-doped SiC, for example, monosilane (SiH₄), methane (CH₄) and phosphine (PH₃) are used as materials and epitaxial growth is performed at a temperature of about 450 to 550° C. Thereby, n-doped SiC having a P concentration of about 1×10²⁰ to 3×10²⁰ cm⁻³ is grown in the concave portion 17. When As is doped as an impurity in place of P, arsine (AsH₃) is used as a material in place of PH₃.

When epitaxially growing a p-doped SiGe, for example, monosilane (SiH₄), monogermane (GeH₄) and diborane (B₂H₆) are used as materials and epitaxial growth is performed at a temperature of about 450 to 550° C. Thereby, p-doped SiGe having a B concentration of about 1×10²⁰ to 3×10²⁰ cm⁻³ is grown in the concave portion 17.

During this epitaxial growth, since a top surface of the gate electrode 7 and a side wall thereof are covered with the gate cap layer 15 and sidewall spacer 8 made of SiN, epitaxial growth of SiC or SiGe is prevented from occurring. Likewise, epitaxial growth of SiC or SiGe is prevented from occurring also over the third mask layer 16.

After the formation of the n-doped SiC or the p-doped SiGe, annealing in an N₂ atmosphere at 1000° C. for about one second is performed for impurity activation. Thereby, the S/D layer 11 is formed within the concave portion 17.

Here, ion implantation for forming the S/D layer 11 may be performed into the concave portion 17 before the epitaxial growth of SiC or SiGe. That is, after the formation of the concave portion 17 and before the epitaxial growth of SiC or SiGe, a predetermined conductivity type impurity such as P or B is ion-implanted into the Si substrate 2 of the concave portion 17. Then, epitaxial growth of doped SiC or SiGe is performed in the concave portion 17 and activation annealing is subsequently performed. In the case of this method, for example, when p is used as an impurity, the ion implantation may be performed under conditions of acceleration energy of about 50 keV and a dose of about 2×10¹⁵ to 8×10¹⁵ cm⁻². Further, for example, when B is used as an impurity, the ion implantation may be performed under conditions of acceleration energy of about 20 keV and a dose of about 2×10¹⁵ to 8×10¹⁵ cm⁻². When thus performing ion-implantation before epitaxially growing the doped SiC or SiGe, a heterosemiconductor interface formed between the Si substrate 2 and the S/D layer 11 can be incorporated into an S/D impurity diffusion layer, so that a reduction in junction leak current caused by the heterointerface can be realized.

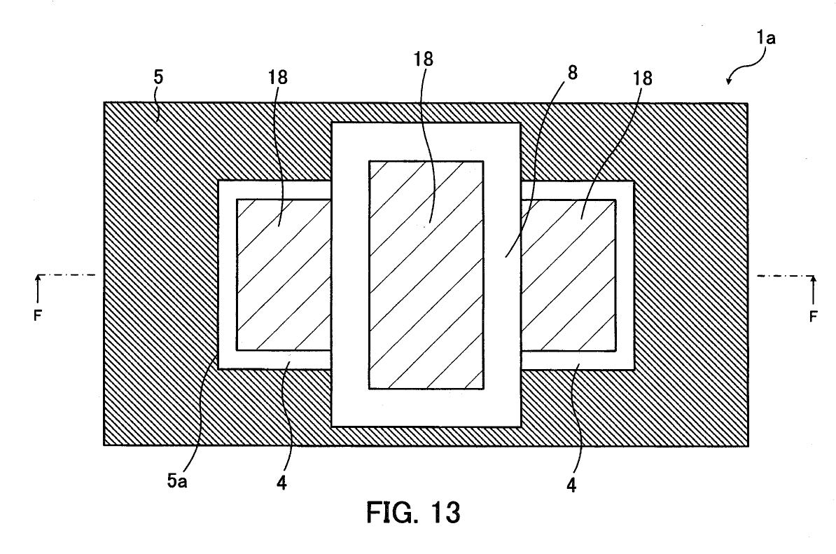

FIG. 13 is a schematic plan view showing an essential part of a sixth forming step of the semiconductor device according to the first embodiment. FIG. 2 is a schematic sectional view taken along the line F-F in FIG. 13.

After the formation of the S/D layer 11, the gate cap layer 15 and the third mask layers 16 are first removed by anisotropic dry etching. Then, a Ni film is formed over the entire surface by a sputter method and annealing is performed at a predetermined temperature. Thereby, Ni silicide 18 is formed over a surface of the gate electrode 7 and a surface of the S/D layer 11. Thus, the semiconductor device 1a having a structure as shown in FIG. 2 is obtained.

The reason why anisotropic dry etching is used for removal of the gate cap layer 15 is as follows. That is, when the sidewall spacer 8 made of SiN is isotropically etched and largely reduced in film thickness, there increases the possibility that when the Ni silicide 18 is formed, an electrical short circuit between the gate electrode 7 and the S/D layer 11 is caused by the Ni silicide 18. Note, however, that a height of the sidewall spacer 8 is reduced to a certain extent even using anisotropic dry etching.

Afterwards, an interlayer insulating film or metal multilayer interconnection may be formed according to normal procedures.

Next, a second embodiment will be described.

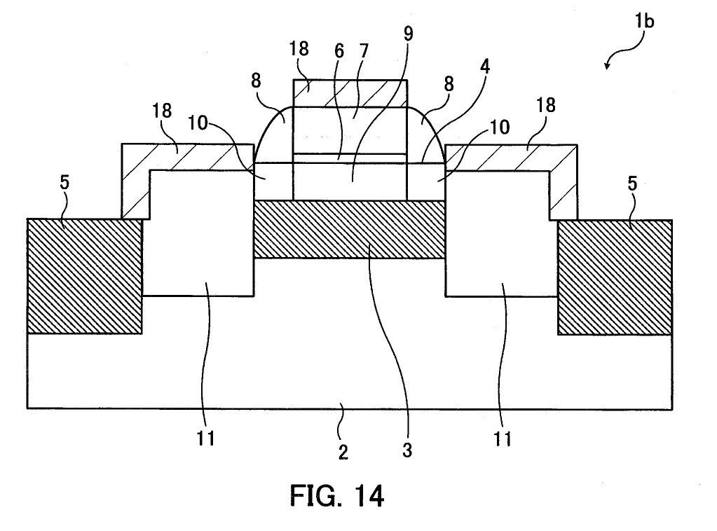

FIG. 14 is a schematic sectional view showing an essential part of a semiconductor device according to a second embodiment.

A semiconductor device 1b of the second embodiment differs from the semiconductor device 1a of the first embodiment mainly in that a top of the STI 5 is lower than that of the S/D layer 11.

In formation of the semiconductor device 1b according to the second embodiment having such a structure, first to third forming steps according to the second embodiment are the same as the first to third forming steps (FIG. 3 to 8) described in the first embodiment. Here, a forming method of the semiconductor device 1b according to the second embodiment will be described with respect to a fourth forming step and subsequent steps, with reference to FIG. 14 and FIGS. 15 to 19.

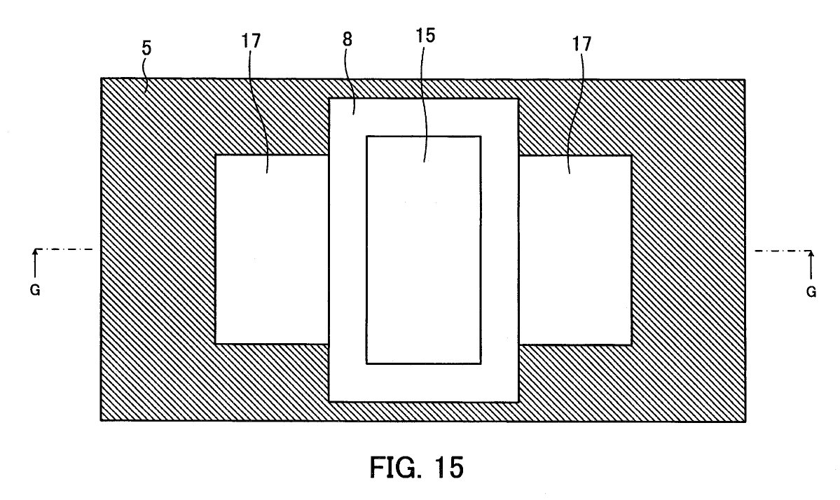

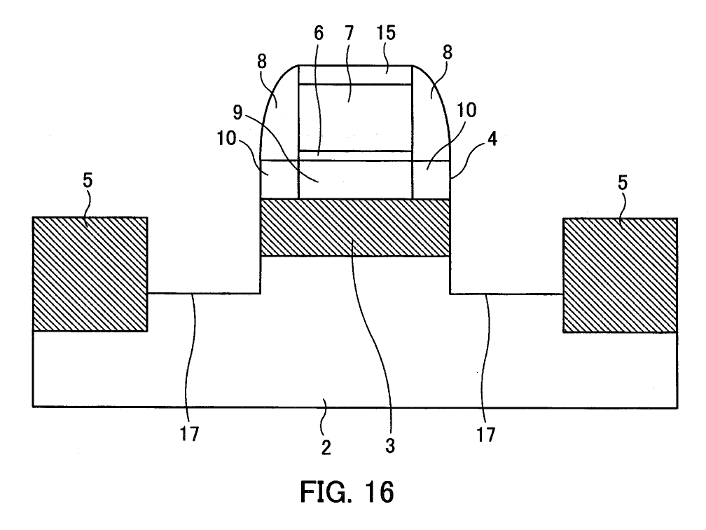

FIG. 15 is a schematic plan view showing an essential part of a fourth forming step of the semiconductor device according to the second embodiment, and FIG. 16 is a schematic sectional view taken along the line G-G in FIG. 15.

After forming up to the sidewall spacer 8 through the forming steps shown in FIGS. 3 to 8, the fourth forming step according to the second embodiment is performed as follows. First, entire surface etching is performed under predetermined conditions. Thereby, the Si layer 4, the buried insulating film 3 and the Si substrate 2 by a predetermined depth are removed to form the concave portion 17 as shown in FIGS. 15 and 16.

At that time, in this second embodiment, the entire surface etching is performed without forming the third mask layer 16 described in the first embodiment. Therefore, formation of the mask layer can be omitted and the concave portion 17 can be efficiently formed. Note, however, that since no mask layer is formed over the STI 5, the STI 5 is also etched by the same thickness as that of the buried insulating film 3 during etching of the buried insulating film 3 and the height of the top of the STI 5 is reduced as compared with the case of the first embodiment.

When forming the concave portion 17, similarly to the case as described in the first embodiment, the following points are considered for the depth of the portion 17: 1) if the Si substrate 2 is exposed, the subsequent epitaxial growth is enabled, and 2) a withstand pressure between adjacent elements is secured.

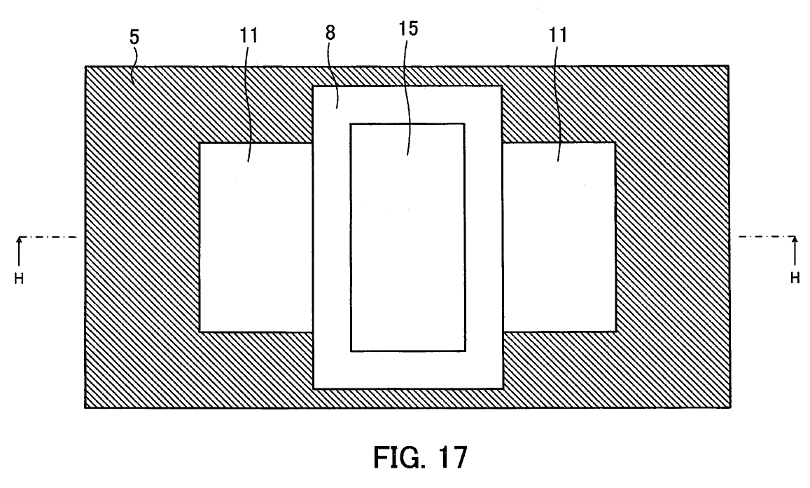

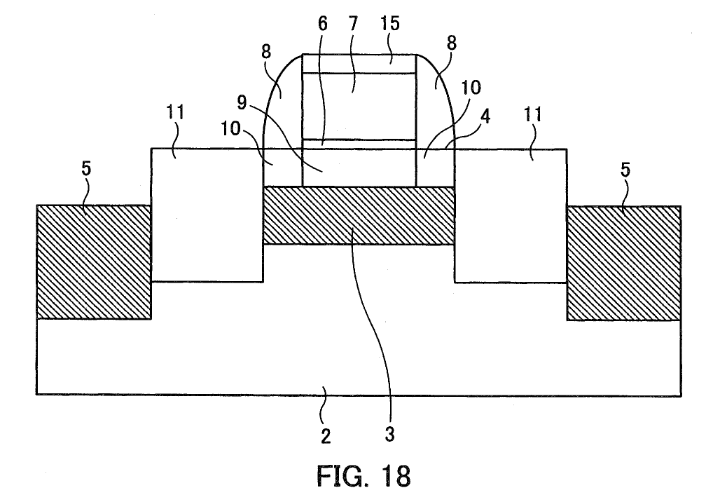

FIG. 17 is a schematic plan view showing an essential part of a fifth forming step of the semiconductor device according to the second embodiment, and FIG. 18 is a schematic sectional view taken along the line H-H in FIG. 17.

After the formation of the concave portion 17, epitaxial growth is performed in the same manner as in the first embodiment. When a transistor to be formed is an n-MOS transistor, n-doped SiC is epitaxially grown in the concave portion 17. When a transistor to be formed is a p-MOS transistor, p-doped SiGe is epitaxially grown in the concave portion 17. Thereafter, annealing in an N₂ atmosphere at 1000° C. for about one second is performed for impurity activation. Thereby, the S/D layer 11 is formed within the concave portion 17.

Here, the following method may be used in the same manner as that described in the first embodiment. That is, after the formation of the concave portion 17 shown in FIGS. 15 and 16 and before the epitaxial growth of SiC or SiGe, a predetermined conductivity type impurity such as P or B is ion-implanted into the Si substrate 2 of the concave portion 17. Then, epitaxial growth of the doped SiC or SiGe is performed and activation annealing is subsequently performed.

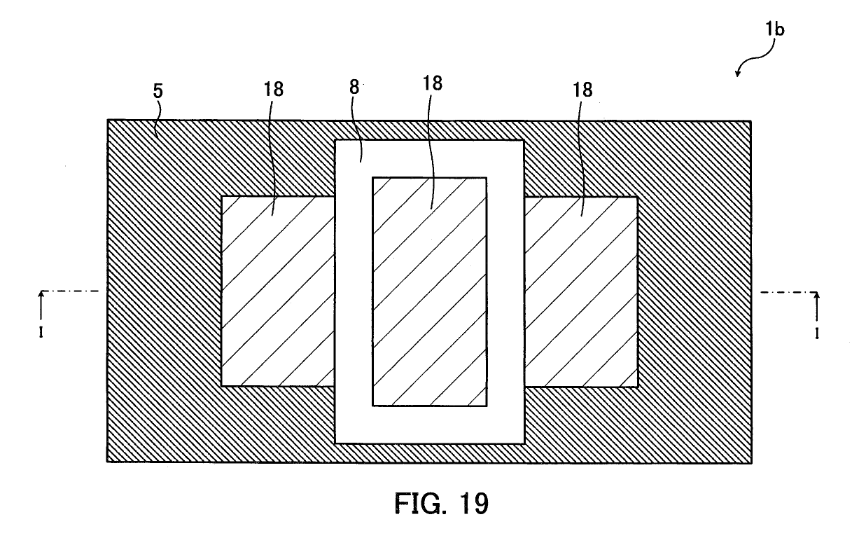

FIG. 19 is a schematic plan view showing an essential part of a sixth forming step of the semiconductor device according to the second embodiment. FIG. 14 is a schematic sectional view taken along the line I-I in FIG. 19.

After the formation of the S/D layer 11, the gate cap layer 15 is first removed by anisotropic dry etching. At that time, the sidewall spacer 8 also is slightly etched. Then, a Ni film is formed over the entire surface by a sputter method and annealing is performed at a predetermined temperature. Thereby, the Ni silicide 18 is formed over a surface of the gate electrode 7 and a surface of the S/D layer 11.

Afterwards, an interlayer insulating film or metal multilayer interconnection may be formed according to normal procedures.

Next, a third embodiment will be described.

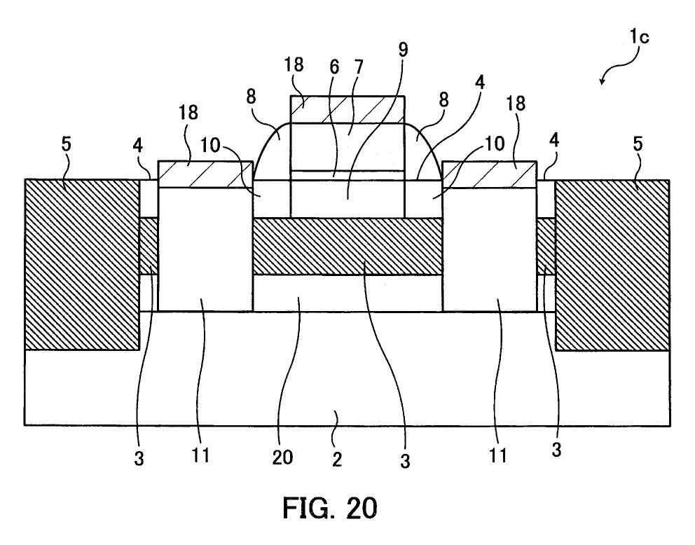

FIG. 20 is a schematic sectional view showing an essential part of a semiconductor device according to a third embodiment.

A semiconductor device 1c of the third embodiment differs from the semiconductor device 1a of the first embodiment in that a punch-through stopper layer 20 for preventing punch-through from occurring between the S/D layers 11 is formed under the buried insulating film 3 immediately below the gate electrode 7 between the S/D layers 11.

This punch-through stopper layer 20 functions as a potential barrier between the S/D layers 11. As a result, even when the channel length is reduced or even when the S/D layer 11 penetrating somewhat deeply into the Si substrate 2 is formed, punch-through can be prevented from occurring between the S/D layers 11.

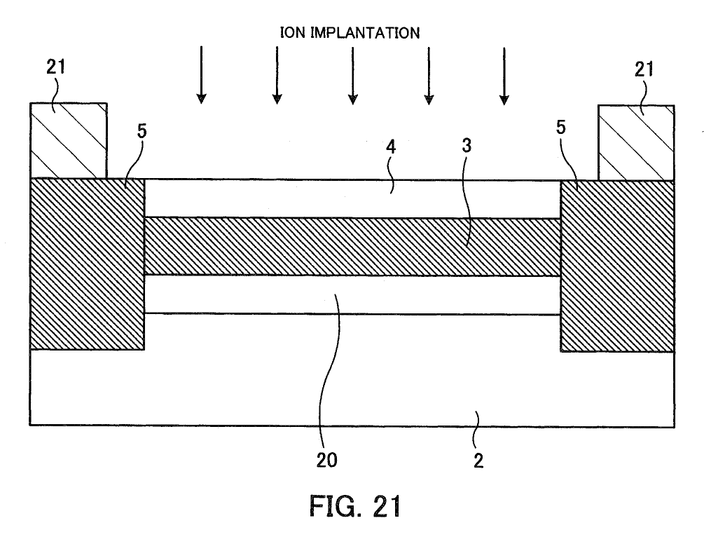

A forming method of the semiconductor device 1c according to the third embodiment having this structure will be described with reference to FIGS. 20 and 21.

FIG. 21 is a schematic sectional view showing an essential part of a punch-through stopper layer forming step according to the third embodiment.

When forming a punch-through stopper layer 20, for example, the following procedures are followed. After the formation of the STI 5 as shown in FIGS. 5 and 6 of the first embodiment and before the formation of the gate insulating film 6, a mask layer 21 is formed over the STI 5 as shown in FIG. 21. Then, impurities having a conductivity type opposite to that of the S/D layer 11 to be formed are ion-implanted into the Si substrate 2 under predetermined conditions.

When a transistor to be formed is an n-MOS transistor, for example, B may be ion-implanted into the Si substrate 2 under conditions of acceleration energy of about 60 keV and a dose of about 2×10¹³ to 8×10¹³ cm⁻². When a transistor to be formed is a p-MOS transistor, for example, P may be ion-implanted into the Si substrate 2 under conditions of acceleration energy of about 150 keV and a dose of about 2×10¹³ to 8×10¹³ cm⁻².

After the formation of the punch-through stopper layer 20, the semiconductor device 1c may be formed by the same procedures as those of the third forming step and subsequent steps according to the first embodiment (FIG. 7 to 13, and FIG. 2). Alternatively, the semiconductor device 1c shown in FIG. 20 may be formed by the same procedures as those of the fourth forming step and subsequent steps according to the second embodiment (FIG. 15 to 19 and FIG. 14) after the third forming step according to the first embodiment (FIGS. 7 and 8).

Next, a fourth embodiment will be described.

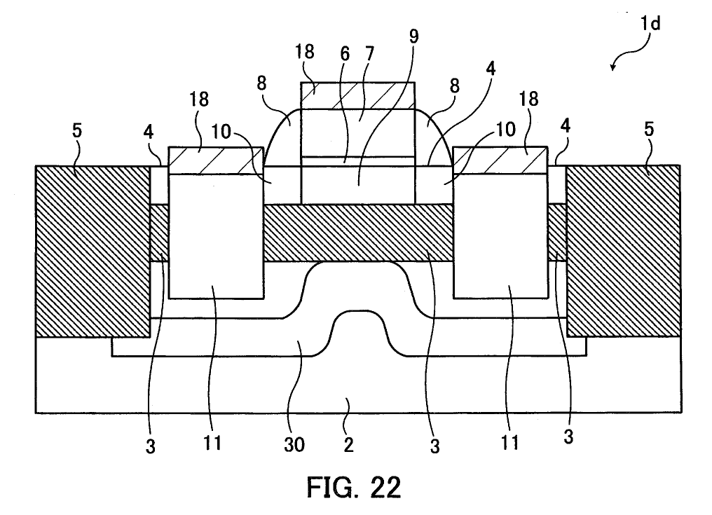

FIG. 22 is a schematic sectional view showing an essential part of a semiconductor device according to a fourth embodiment.

A semiconductor device 1d of the fourth embodiment differs from the semiconductor device 1c of the third embodiment in that a punch-through stopper layer 30 is formed under the buried insulating film 3 immediately below the gate electrode 7 between the S/D layers 11 so as not to contact with the bottom of the S/D layer 11.

The punch-through stopper layer 30 according to the fourth embodiment is formed in the same manner as in the case of the third embodiment. That is, when a transistor to be formed is an n-MOS transistor, a p-type impurity such as B is used and implanted under predetermined conditions, whereas when a transistor to be formed is a p-MOS transistor, an n-type impurity such as P is used and implanted under predetermined conditions. At this time, the S/D layer 11 and the punch-through stopper layer 30 have opposite conductivity types. Accordingly, when the S/D layer 11 and the punch-through stopper layer 30 are formed separately from each other, parasitic capacitance can be more reduced than the case where the S/D layer 11 and the punch-through stopper layer 30 are formed in contact with each other.

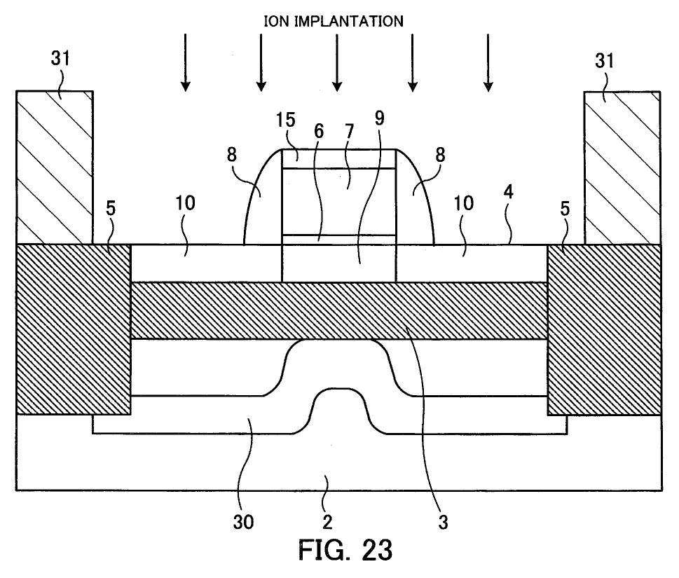

A forming method of the semiconductor device 1d according to the fourth embodiment having this structure will be described with reference to FIGS. 22 and 23.

FIG. 23 is a schematic sectional view showing an essential part of a punch-through stopper layer forming step according to the fourth embodiment.

When forming a punch-through stopper layer 30, for example, the following procedures are followed. After the formation of the sidewall spacer 8 as shown in FIGS. 7 and 8 of the first embodiment and before the formation of the concave portion 17, a mask layer 31 is formed over the STI 5. Then, predetermined impurities are ion-implanted into the Si substrate 2 under predetermined conditions. Thereby, the punch-through stopper layer 30 having the following impurity profile is formed within the Si substrate 2. That is, the layer 30 is shallow in a region immediately below the gate electrode 7 and the sidewall spacer 8 and is deep in a region other than the above-described region.

The ion implantation is performed as follows. When a transistor to be formed is an nMOS transistor, for example, B is ion-implanted into the Si substrate 2 under conditions of acceleration energy of about 80 keV and a dose of about 2×10¹³ to 8×10¹³ cm⁻². When a transistor to be formed is a p-MOS transistor, for example, P is ion-implanted into the Si substrate 2 under conditions of acceleration energy of about 200 keV and a dose of about 2×10¹³ to 8×10¹³ cm⁻².

After the formation of the punch-through stopper layer 30, the semiconductor device 1d may be formed by the same procedures as those of the fourth forming step and subsequent steps according to the first embodiment (FIGS. 9 to 13, and FIG. 2). Alternatively, the semiconductor device 1d shown in FIG. 22 may be formed by the same procedures as those of the fourth forming step and subsequent steps according to the second embodiment (FIG. 15 to 19, and FIG. 14). It is desired that when forming the concave portion 17, its bottom is located at a position not reaching the punch-through stopper layer 30 but reaching the Si substrate 2.

In addition, the punch-through stopper layer 30 can also be formed by the following procedures. After the formation of the gate electrode 7 in the third forming step shown in FIGS. 7 and 8 and before the formation of the sidewall spacer 8, the mask layer 31 is formed and then, predetermined impurities are ion-implanted under predetermined conditions, in the same manner as in the above-described case. In this case, the ion implantation conditions and the procedures after the formation of the punch-through stopper layer 30 can be set to be the same as those of the above-described case where the punch-through stopper layer 30 is formed after the formation of the sidewall spacer 8.

Next, a fifth embodiment will be described.

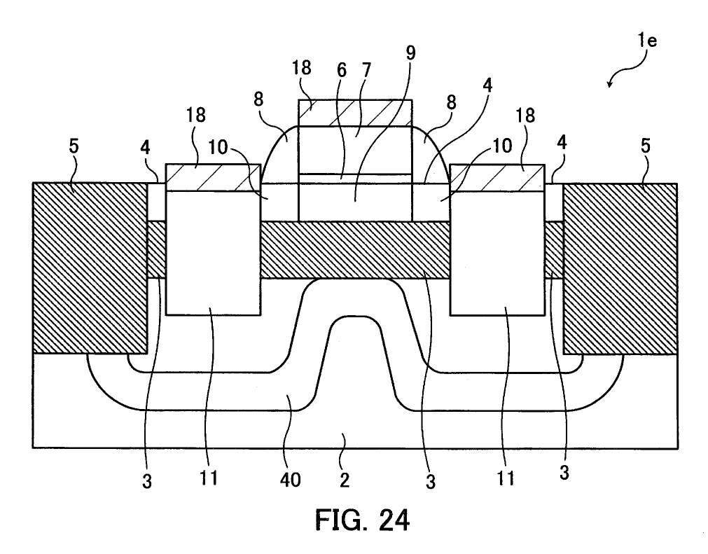

FIG. 24 is a schematic sectional view showing an essential part of a semiconductor device according to a fifth embodiment.

A semiconductor device 1e of the fifth embodiment is the same as the semiconductor device 1d of the fourth embodiment in that a punch-through stopper layer 40 is formed under the buried insulating film 3 immediately below the gate electrode 7 between the S/D layers 11 so as not to contact with the S/D layer 11. However, the semiconductor device 1e differs from the semiconductor device 1d in the forming method thereof.

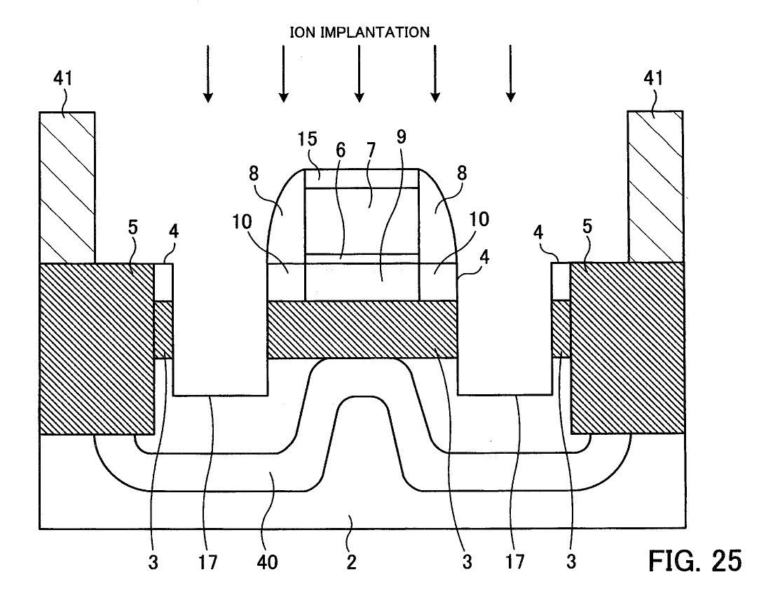

FIG. 25 is a schematic sectional view showing an essential part of a punch-through stopper layer forming step according to the fifth embodiment.

In the fifth embodiment, a punch-through stopper layer 40 is formed by the following procedures. After forming the concave portion 17 as shown in FIGS. 9 and 10 according to the first embodiment, a mask layer 41 is formed over the STI 5 and then, predetermined impurities are ion-implanted into the Si substrate 2 under predetermined conditions. On this occasion, the ion implantation conditions can be set to be the same as those described in the fourth embodiment.

After the formation of the punch-through stopper layer 40, a suitable mask layer is formed. Then, the same procedures as those of the fifth forming step and subsequent steps of the first embodiment (FIG. 11 to 13, and FIG. 2) may be followed to form the semiconductor device 1e shown in FIG. 24. Alternatively, after the fourth forming step of the second embodiment (FIGS. 15 and 16), the mask layer 41 and the punch-through stopper layer 40 are similarly formed in this order. Then, the same procedures as those of the fifth forming step and subsequent steps of the second embodiment (FIG. 17 to 19, and FIG. 14) may be followed to form the semiconductor device 1e.

According to the above-described forming method, a space can be widely and surely secured between the S/D layer 11 and the punch-through stopper layer 40, as compared with the fourth embodiment.

Next, a sixth embodiment will be described.

In the first to fifth embodiments, description is made on the case of forming an nMOS transistor or pMOS transistor as the semiconductor devices 1a to 1e. In this sixth embodiment, description will be made on a case of forming a CMOS transistor. Here, description will be made by taking as an example a case of applying a forming method of the semiconductor device 1a according to the first embodiment to CMOS formation.

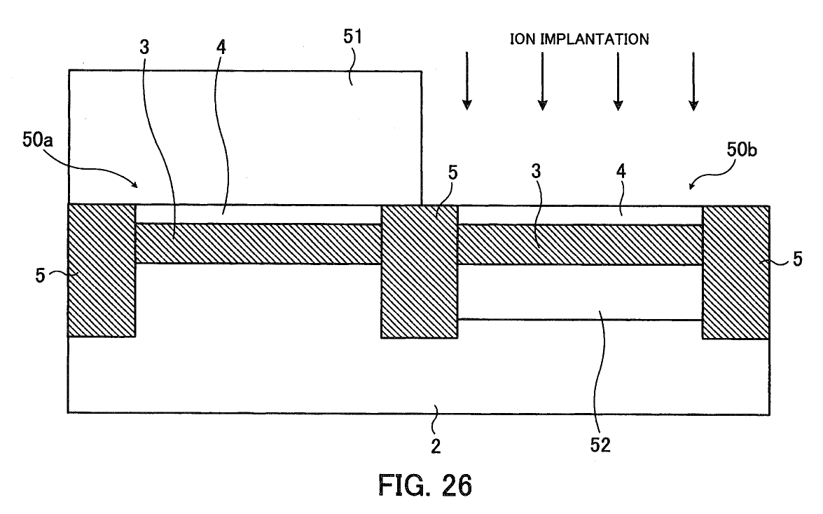

FIG. 26 is a schematic sectional view showing an essential part of a first forming step of a semiconductor device according to a sixth embodiment.

After preparing an SOI substrate including the p-type Si substrate 2, the buried insulating film 3 made of SiO₂ having a thickness of about 100 nm and the Si layer 4 having a thickness of about 50 nm, a trench is formed in a portion to be formed as an element isolation region. Then, a high-density plasma oxide film having a thickness of about 250 to 400 nm is deposited over the entire surface and planarized by CMP. Thereby, the STI 5 is formed in the trench.

Then, a region (nMOS transistor forming region) 50a in which an nMOS transistor is formed is covered with a resist 51 and P is ion-implanted into a region (pMOS transistor forming region) 50b in which a pMOS transistor is formed. Thereby, an n-type diffusion layer 52 is formed under the buried insulating film 3 in the pMOS transistor forming region 50b. Thereafter, the resist 51 is removed.

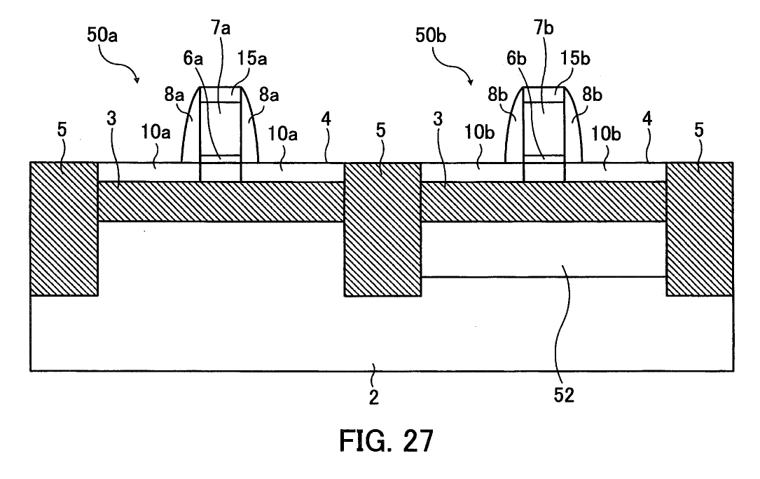

FIG. 27 is a schematic sectional view showing an essential part of a second forming step of the semiconductor device according to the sixth embodiment.

After the formation of the n-type diffusion layer 52 in the pMOS transistor forming region 50b, ion implantation is performed into the Si layer 4 to adjust the threshold voltage in each of the nMOS transistor forming region 50a and the pMOS transistor forming region 50b. Into the nMOS transistor forming region 50a, for example, B is ion-implanted under conditions of acceleration energy of about 15 keV and a dose of about 2×10¹³ to 3×10¹³ cm⁻². Into the PMOS transistor forming region 50b, for example, P is ion-implanted under conditions of acceleration energy of about 40 keV and a dose of about 2×10¹³ to 3×10¹³ cm⁻².

After this ion implantation, a SiON film having a thickness of about 2 nm is formed over the Si layer 4. Then, polysilicon having a thickness of about 100 nm and a SiN film having a thickness of about 10 nm are sequentially deposited over the SiON film. Thereafter, ion implantations under predetermined conditions are performed respectively into the nMOS transistor forming region 50a and the pMOS transistor forming region 50b. Into the nMOS transistor forming region 50a, for example, P is ion-implanted under conditions of a dose of about 8×10¹⁵ cm⁻². Into the pMOS transistor forming region 50b, for example, B is ion-implanted under conditions of a dose of about 8×10¹⁵ cm⁻².

Thereafter, anisotropic etching is performed, thereby forming gate insulating films 6a and 6b, gate electrodes 7a and 7b and gate cap layers 15a and 15b in the nMOS transistor forming region 50a and the pMOS transistor forming region 50b, respectively.

After the formation of the gate electrodes 7a and 7b and the gate cap layers 15a and 15b, using them as masks, ion implantation is performed into the Si layer 4 to form S/D extension regions 10a and 10b in the nMOS transistor forming region 50a and the pMOS transistor forming region 50b, respectively. Into the nMOS transistor forming region 50a, for example, As is ion-implanted under conditions of a dose of about 6×10¹⁴ cm⁻². Into the pMOS transistor forming region 50b, for example, B is ion-implanted under conditions of a dose of about 6×10¹⁴ cm⁻².

Thereafter, a SiN film having a thickness of about 30 nm is deposited over the entire surface and anisotropic etching is performed. Thereby, sidewall spacers 8a and 8b are formed on side walls of the gate electrode 7a and the gate cap layer 15a as well as on side walls of the gate electrode 7b and the gate cap layer 15b, respectively.

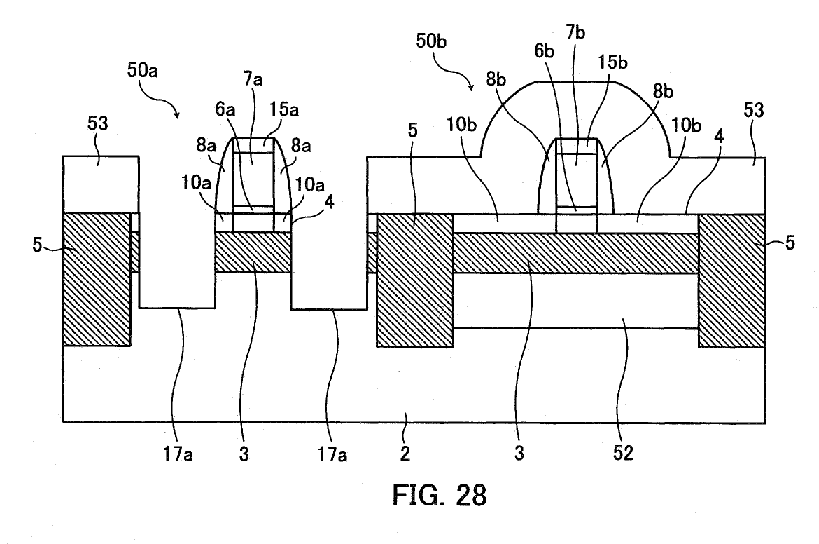

FIG. 28 is a schematic sectional view showing an essential part of a third forming step of the semiconductor device according to the sixth embodiment.

After the formation of the sidewall spacers 8a and 8b, a SiN film having a thickness of about 10 nm is deposited over the entire surface. Then, using a resist mask, the SiN film is first etched such that it remains in the pMOS transistor forming region 50b, in other words, such that the nMOS transistor forming region 50a is opened. Thereby, a mask layer 53 is formed. Note, however, that in the nMOS transistor forming region 50a, the mask layer 53 is formed such that a region on the inner side of the STI 5 delimiting the region 50a is opened.

Then, using the mask layer 53, the gate cap layer 15a and the sidewall spacer 8a as masks, the Si layer 4, the buried insulating film 3 and the Si substrate 2 by a predetermined depth are etched. Thereby, a concave portion 17a is formed in the nMOS transistor forming region 50a. During the formation of the concave portion 17a, first, the Si layer 4 is anisotropically dry etched using a mixed gas of HBr and O₂ as an etchant. Next, the buried insulating film 3 is anisotropically dry etched using CF₄ as an etchant. Finally, the Si substrate 2 is anisotropically dry etched using a mixed gas of HBr and O₂ as an etchant. More specifically, when forming the concave portion 17a, a top surface of the gate electrode 7a, a portion close to the side wall of the gate electrode 7a and at least a part of the S/D layer of another semiconductor device formed over the Si layer 4 are covered with the mask layer 53 and the like. Further, etching is performed using the mask layer 53 having etching resistance different from those of any of the Si layer 4, the buried insulating film 3 and the Si substrate 2.

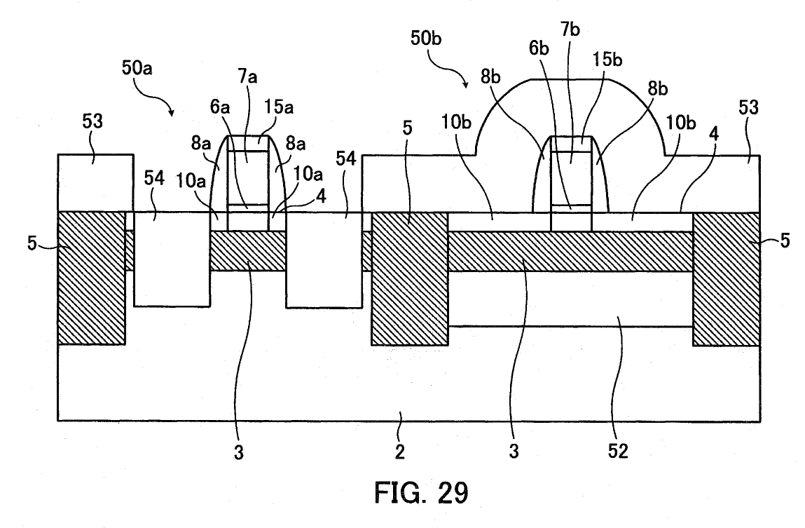

FIG. 29 is a schematic sectional view showing an essential part of a fourth forming step of the semiconductor device according to the sixth embodiment.

After the formation of the concave portion 17a, epitaxial growth at a temperature of about 450 to 550° C. is performed using SiH₄, CH₄ and PH₃ as materials. Thereby, an n-doped SiC layer 54 having a P concentration of about 1×10²⁰ to 3×10²⁰ cm⁻³ is formed in the concave portion 17a. Thereafter, the mask layer 53 is removed.

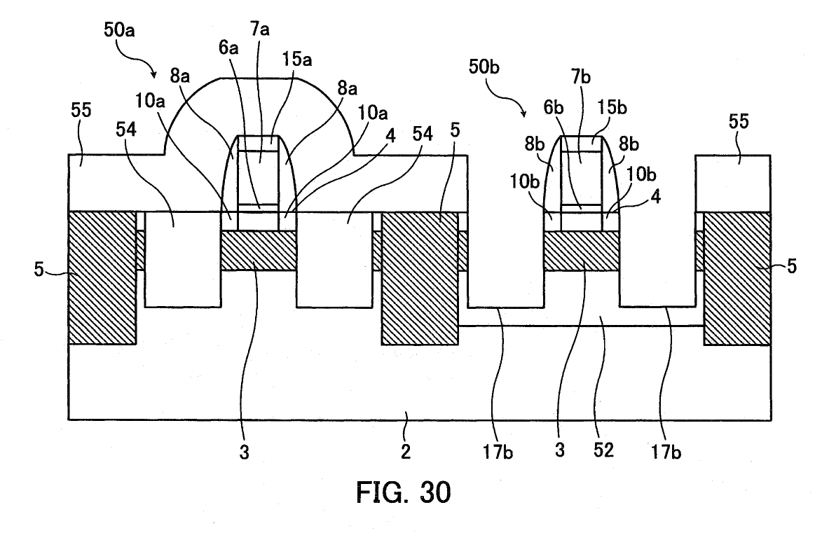

FIG. 30 is a schematic sectional view showing an essential part of a fifth forming step of the semiconductor device according to the sixth embodiment.

After the formation of the n-doped SiC layer 54, a SiN film having a thickness of about 10 nm is deposited over the entire surface. Then, the SiN film is etched such that a region on the inner side of the STI 5 in the pMOS transistor forming region 50b is opened. Thereby, a mask layer 55 is formed. Then, using the mask layer 55, the gate cap layer 15b and the sidewall spacer 8b as masks, the Si layer 4 and the buried insulating film 3 and the Si substrate 2 by a predetermined depth are etched. Thereby, a concave portion 17b is formed in the PMOS transistor forming region 50b. During the formation of the concave portion 17b, etching can be performed under the same conditions as those in the case of forming the concave portion 17a in the nMOS transistor forming region 50a.

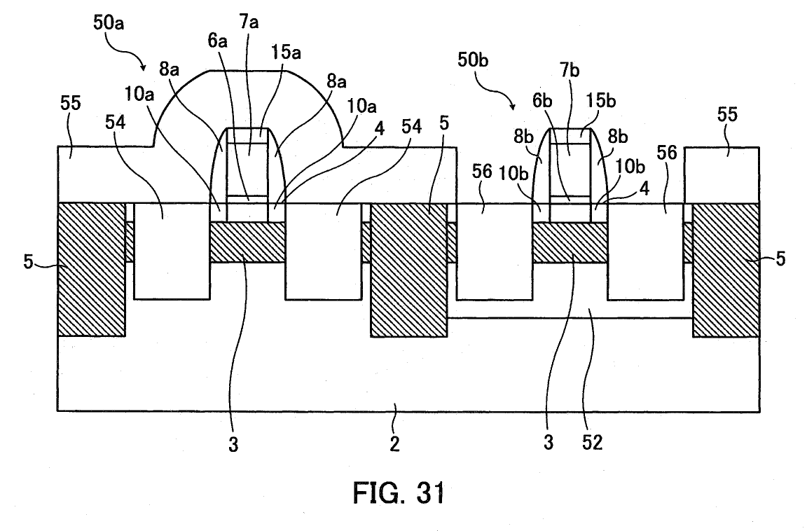

FIG. 31 is a schematic sectional view showing an essential part of a sixth forming step of the semiconductor device according to the sixth embodiment.

After the formation of the concave portion 17b, epitaxial growth at a temperature of about 450 to 550° C. is performed using SiH₄, GeH₄ and B₂H₆ as materials. Thereby, a p-doped SiGe layer 56 having a B concentration of about 1×10²⁰ to 3×10²⁰ cm⁻³ is formed in the concave portion 17b.

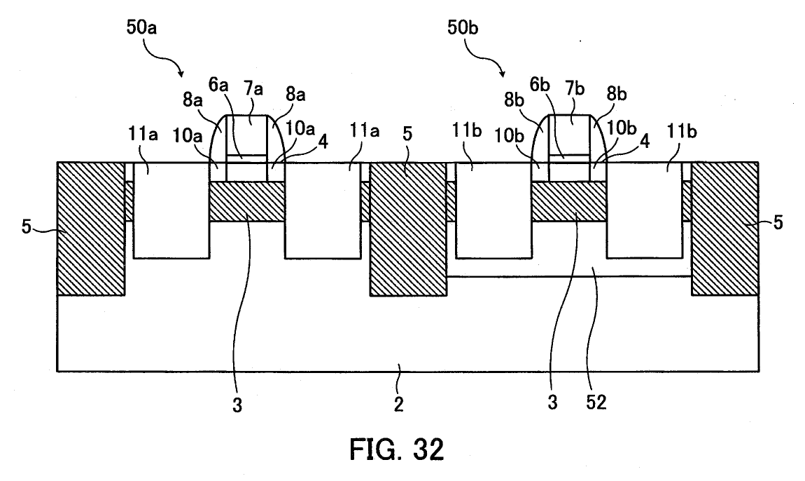

FIG. 32 is a schematic sectional view showing an essential part of a seventh forming step of the semiconductor device according to the sixth embodiment.

After the formation of the p-doped SiGe layer 56, the mask layer 55 is removed and the activation annealing in N₂ atmosphere at 1000° C. for about one second is performed. Thereby, impurities contained in the n-doped SiC layer 54 of the nMOS transistor forming region 50a as well as in the p-doped SiGe layer 56 of the pMOS transistor forming region 50b are activated to form S/D layers 11a and 11b in the nMOS transistor forming region 50a and the pMOS transistor forming region 50b, respectively.

Here, predetermined impurities are doped during the epitaxial growth of SiC and SiGe. However, the following method may be used instead. That is, after the formation of the concave portions 17a and 17b and before the epitaxial growth of SiC and SiGe, P and B are ion-implanted into the Si substrate 2 of the concave portions 17a and 17b, respectively. Then, the epitaxial growth of doped SiC and SiGe and the activation annealing are performed. In that case, for example, when P is used as an impurity, the ion implantation may be performed under conditions of acceleration energy of about 50 keV and a dose of about 2×10¹⁵ to 8×10¹⁵ cm⁻². Further, for example, when B is used as an impurity, the ion implantation may be performed under conditions of acceleration energy of about 20 keV and a dose of about 2×10¹⁵ to 8×10¹⁵ cm⁻².

After the formation of the S/D layers 11a and 11b, Ni silicide is formed in the same manner as in the first embodiment. Afterwards, an interlayer insulating film or metal multilayer interconnection is formed according to normal procedures. Thus, a CMOS transistor is completed.

Here, description is made by taking as an example a case of applying a forming method according to the first embodiment to CMOS formation. Similarly to this case, the forming methods according to the second to fifth embodiments can also be of course applied to the CMOS formation.

As described above, when forming the MOS transistor using the SOI substrate including the Si substrate 2 having formed thereover the thin Si layer 4 through the buried insulating film 3, the S/D layers 11, 11a and 11b having a crystal structure with a lattice constant different from that of a Si crystal are formed by epitaxial growth from the surfaces of the Si substrate 2 and Si layer 4 exposed in the concave portions 17, 17a and 17b. As a result, there are formed the S/D layers 11, 11a and 11b which penetrate through the Si layer 4 and the buried insulating film 3 into the Si substrate 2 and which have a lattice constant different from those of the Si substrate 2 and the Si layer 4.

According to the above-described forming method, the S/D layers 11, 11a and 11b can be formed to have at least a thickness reaching the Si substrate 2 as a support substrate from the surface of the SOI substrate. Therefore, sufficient stress is generated in a channel region, so that improvement in the carrier mobility can be achieved. Further, the channel region is formed in the thin Si layer 4. Therefore, control by the gate electrodes 7, 7a and 7b is performed with high accuracy, so that suppression in the short channel effect can be achieved. Accordingly, the high-speed and high-performance semiconductor devices 1a to 1e can be obtained.

The above-described forming conditions are one example and the conditions can be arbitrarily changed according to demand characteristics of a semiconductor device to be formed.

In the present invention, a gate electrode is formed over a thin film semiconductor layer formed through a buried insulating film over a semiconductor substrate. Further, S/D layers which penetrate through the thin film semiconductor layer and the buried insulating film into the semiconductor substrate and which have a crystal structure with a lattice constant different from that of the thin film semiconductor layer are formed on both sides of the gate electrode. As a result, a short channel effect can be suppressed as well as improvement in the carrier mobility can be efficiently achieved. Thus, a high-speed and high-performance semiconductor device can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device using a substrate including a semiconductor substrate having formed thereover a thin film semiconductor layer through a buried insulating film; the semiconductor device comprising:
a gate electrode formed over the thin film semiconductor layer through a gate insulating film; and
a source/drain layer formed on both sides of the gate electrode, which penetrates through the thin film semiconductor layer and the buried insulating film into the semiconductor substrate and which has a crystal structure with a lattice constant different from that of the thin film semiconductor layer.

2. The semiconductor device according to claim 1, wherein in an n-channel type, a lattice constant of the source/drain layer is smaller than that of the thin film semiconductor layer.

3. The semiconductor device according to claim 2, wherein the semiconductor substrate is a silicon substrate, the thin film semiconductor layer is a silicon layer and the source/drain layer is a silicon carbide layer.

4. The semiconductor device according to claim 1, wherein in a p-channel type, a lattice constant of the source/drain layer is larger than that of the thin film semiconductor layer.

5. The semiconductor device according to claim 4, wherein the semiconductor substrate is a silicon substrate, the thin film semiconductor layer is a silicon layer and the source/drain layer is a silicon germanium layer.

6. The semiconductor device according to claim 1, wherein the gate electrode and the source/drain layer are formed in an element region delimited by an element isolation insulating film, the film being formed to penetrate through the thin film semiconductor layer and the buried insulating film into the semiconductor substrate.

7. The semiconductor device according to claim 6, wherein the element isolation insulating film is formed such that the bottom of the element isolation insulating film is located at a position deeper than that of the source/drain layer.

8. The semiconductor device according to claim 6, wherein the element isolation insulating film is formed such that the top of the element isolation insulating film is located at a position lower than that of the source/drain layer.

9. The semiconductor device according to claim 1, wherein a region sandwiched between the source/drain layers within the semiconductor substrate immediately below the gate electrode is provided with an impurity layer containing an impurity of a conductivity type opposite to that of the source/drain layer, the opposite conductivity type impurity having a concentration higher than that contained in the semiconductor substrate.

10. The semiconductor device according to claim 9, wherein the impurity layer is provided separately from the source/drain layer.

11. A method of manufacturing a semiconductor device using a substrate including a semiconductor substrate having formed thereover a thin film semiconductor layer through a buried insulating film, the method comprising the steps of:
(a) forming a gate electrode over the thin film semiconductor layer through a gate insulating film;
(b) forming a concave portion on both sides of the gate electrode, the concave portion penetrating through the thin film semiconductor layer and the buried insulating film into the semiconductor substrate; and
(c) forming in the concave portion a source/drain layer having a crystal structure with a lattice constant different from that of the thin film semiconductor layer.

12. The manufacturing method according to claim 11, wherein in the step (c), the source/drain layer is formed by epitaxial growth from the semiconductor substrate.

13. The manufacturing method according to claim 11, further comprising the step of:
forming an element isolation insulating film to penetrate through the thin film semiconductor layer and the buried insulating film into the semiconductor substrate, wherein:
in the step (a), after the element isolation insulating film is formed, the gate electrode is formed in an element region delimited by the element isolation insulating film; and
in the step (b), the concave portion is formed on both sides of the gate electrode in the element region.

14. The manufacturing method according to claim 13, wherein in forming the concave portion, at least the thin film semiconductor layer and the buried insulating film on both sides of the gate electrode are etched while covering the element isolation insulating film with a mask layer.

15. The manufacturing method according to claim 13, wherein:
in forming the concave portion, at least the thin film semiconductor layer and the buried insulating film on both sides of the gate electrode are etched; and
in etching the buried insulating film, the element isolation insulating film is etched simultaneously with the buried insulating film.

16. The manufacturing method according to claim 13, wherein:
in forming the concave portion, another element region isolated by the element isolation insulating film is covered with a mask layer;
the source/drain layer is formed in the concave portion; and
after the formation of the source/drain layer, the element region is covered with a mask layer to form a concave portion and a source/drain layer in the another element region.

17. The manufacturing method according to claim 11, further comprising, before the steps (a), (b) and (c), the step of:
(d) ion-implanting an impurity of a conductivity type opposite to that of the source/drain layer into the semiconductor substrate from the thin film semiconductor layer side and forming an impurity layer in a region near an interface between the semiconductor substrate and the buried insulating film, the opposite conductivity type impurity having a concentration higher than that contained in the semiconductor substrate.

18. The manufacturing method according to claim 11, further comprising, after the step (a) and before the steps (b) and (c), the step of:
(e) ion-implanting an impurity of a conductivity type opposite to that of the source/drain layer into the semiconductor substrate from the thin film semiconductor layer side and forming an impurity layer in a region including the vicinity of an interface between the semiconductor substrate and buried insulating film immediately below the gate electrode, the opposite conductivity type impurity having a concentration higher than that contained in the semiconductor substrate.

19. The manufacturing method according to claim 11, comprising, between the steps (b) and (c), the step of:
(e) ion-implanting an impurity of a conductivity type opposite to that of the source/drain layer into the semiconductor substrate from the thin film semiconductor layer side and forming an impurity layer in a region including the vicinity of an interface between the semiconductor substrate and buried insulating film immediately below the gate electrode, the opposite conductivity type impurity having a concentration higher than that contained in the semiconductor substrate.

20. The manufacturing method according to claim 11, wherein:
in forming the concave portion, a top surface of the gate electrode, a portion close to a side wall of the gate electrode, and at least a part of a source/drain layer of another semiconductor device formed over the thin film semiconductor layer are covered with a mask layer, and
the mask layer has etching resistance different from those of any of the thin film semiconductor layer, the buried insulating film and the semiconductor substrate.
